(19) United States
(12) Patent Application Publication
(10) Pub. No.: US 2009/0241668 A1
(43) Pub. Date: Oct. 1, 2009

(54) Acceleration sensor package

(75) Inventor: Younseok JANG, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/382,796

(22) Filed: Mar. 24, 2009

(30) Foreign Application Priority Data
Mar. 25, 2008 (JP) 2008-077212

(51) Int. Cl. G01P 15/125

(52) U.S. Cl. 73/514.32

(57) ABSTRACT

The acceleration sensor package comprises an acceleration sensor chip having a pad forming surface formed with a plurality of pads at at least one edge portion, a control chip having a terminal forming surface formed with connecting terminals, and a case body having a storage concave section for accommodating the acceleration sensor chip and the control chip therein and bottom face terminals respectively disposed at positions corresponding to the pads at a bottom face of the storage concave section. The pads of the acceleration sensor chip are respectively electrically connected to the bottom face terminals of the case body. A back surface located on the side opposite to the terminal forming surface, of the control chip is mated with its corresponding back surface located on the side of the pad forming surface, of the acceleration sensor chip.

### BACKGROUND OF THE INVENTION

The present invention relates to an acceleration sensor package mounted in transport equipment such as an automobile and an airplane, and a portable terminal or the like and used for detection of acceleration thereof.

A conventional acceleration sensor package is configured so as to accommodate an acceleration sensor chip having a pad forming surface formed with a plurality of pads at an edge portion and having a weight section swingably supported by flexible portions respectively provided with piezoelements into a concave section provided at a back surface of a control chip located on the side opposite to a terminal forming surface of the control chip having the terminal forming surface formed with a plurality of connecting terminals. A back surface located on the side opposite to the pad forming surface of the acceleration sensor chip is bonded onto a base by die bonding agents. The pads of the acceleration sensor chip and wirings provided at the base are connected by wires each comprised of a metal thin line. The acceleration sensor chip is accommodated into the concave section of the control chip (refer to, for example, a patent document 1 (Japanese Unexamined Patent Publication No. 2006-179607 (paragraphs 0040-0079, FIG. 2 and FIG. 3)).

The above related art is however accompanied by a problem that since the pads of the acceleration sensor chip whose back surface is jointed to the base and the wirings provided at the base are connected by the wires each comprised of the metal thin line, and the acceleration sensor chip is accommodated into the concave section of the control chip, a gap or clearance for accommodating the wires therein is required to be provided between the bottom face of the concave section and the pad forming surface of the acceleration sensor and thinning of the acceleration sensor package becomes difficult.

A problem also arises in that since the weight section is swingably supported by the flexible portions in the acceleration sensor chip, the flexible portions of the acceleration sensor chip are likely to be damaged when the space for accommodating the wires therein is excessively large, due to excessive acceleration impulsively produced, for example, where a portable terminal or the like with the acceleration sensor package attached thereto is dropped or where an automobile with the acceleration sensor package attached thereto runs up on the curb or the like.

### SUMMARY OF THE INVENTION

The present invention has been made to solve the above problems. It is therefore an object of the present invention to provide means for achieving thinning of an acceleration sensor package and preventing damage of flexible portions of an acceleration sensor chip.

According to one aspect of the present invention, for attaining the above object, there is provided an acceleration sensor package comprising an acceleration sensor chip having a pad forming surface formed with a plurality of pads at at least one edge portion; a control chip having a terminal forming surface formed with connecting terminals; and a case body having a storage concave section for accommodating the acceleration sensor chip and the control chip therein and bottom face terminals respectively disposed at positions corresponding to the pads at a bottom face of the storage concave section, wherein the pads of the acceleration sensor chip are respectively electrically connected to the bottom face terminals of the case body, and wherein a back surface located on the side opposite to the terminal forming surface, of the control chip is mated with a back surface located on the side opposite to the pad forming surface, of the acceleration sensor chip.

Thus, the present invention brings about advantageous effects in that wires respectively connected to pads of an acceleration sensor chip become unnecessary thereby to make it possible to minimize the height of a chip laminated body having the acceleration sensor chip and a control chip laminated on each other and achieve thinning of an acceleration sensor package, and the bottom face of a storage concave section can be allowed to function as a stopper for restricting swinging of a weight section of the semiconductor sensor chip thereby to make it possible to prevent damage of flexible portions of the acceleration sensor chip.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is an explanatory diagram showing a section of an acceleration sensor package according to a first preferred embodiment;

FIG. 2 is an explanatory diagram depicting a chip laminated body of the first preferred embodiment as viewed from its pad forming surface side;

FIG. 3 is an explanatory diagram illustrating a section of an acceleration sensor package according to a second preferred embodiment; and

FIG. 4 is an explanatory diagram showing a chip laminated body of the second preferred embodiment as viewed from its pad forming surface side.

### DETAILED DESCRIPTION OF THE PREFERRED EMBODIMENTS

Preferred embodiments of an acceleration sensor package according to the present invention will hereinafter be described with reference to the accompanying drawings.

### First Preferred Embodiment

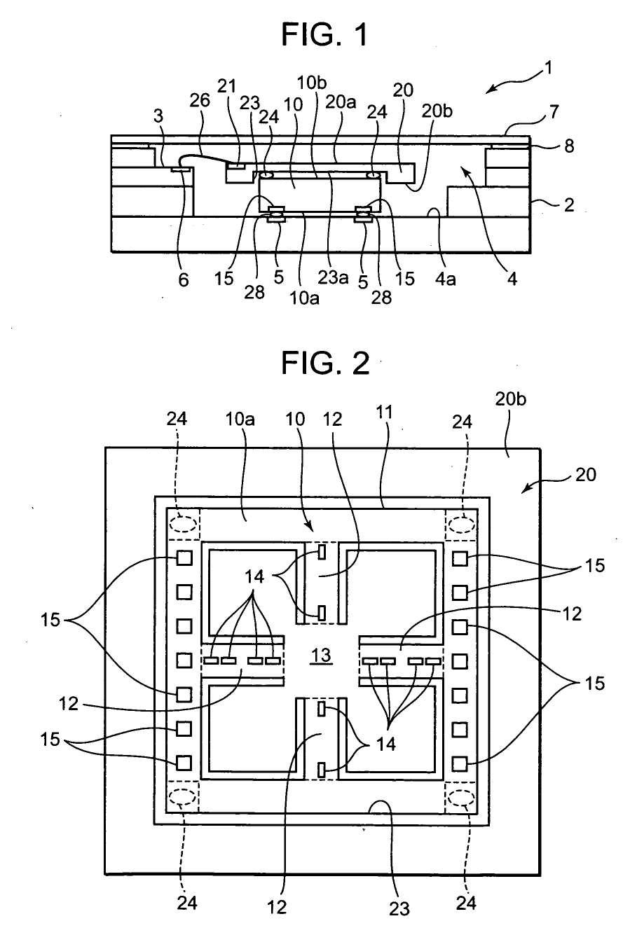

FIG. 1 is an explanatory diagram showing a section of an acceleration sensor package according to a first preferred embodiment, and FIG. 2 is an explanatory diagram illustrating a chip laminated body of the first preferred embodiment as viewed from its pad forming surface side, respectively.

In FIG. 1, reference numeral 1 indicates the acceleration sensor package.

Reference numeral 2 indicates a case body, which is a dead-end frame body made of ceramics or the like, having an accommodation or storage concave section 4 formed with an intermediate stage portion 3. A plurality of internal terminals 6 electrically connected by unillustrated wires to a plurality of bottom face terminals 5 provided at a bottom face 4a of the storage concave section 4 are provided at a steplike surface of the intermediate stage portion 3.

Reference numeral 7 indicates a cover, which is a plate-like member fabricated by a thin plate such as ceramics, a metal or a resin material. The cover 7 is bonded onto its corresponding upper surface of a side plate of the case body 2 by an adhesive material 8 such as an adhesive and prevents external intrusion of dust or the like into the storage concave section 4.

Reference numeral 10 indicates an acceleration sensor chip (hereinafter called “sensor chip 10”) and has the function of detecting acceleration components of three axes comprising an X axis, a Y axis and a Z axis orthogonal to one another.

In FIG. 2, reference numeral 11 indicates a support section, which is a rectangular frame body comprised of silicon (Si), which is formed at the edge portion of the sensor chip 10. A weight section 13 swingably supported by flexible portions 12 formed of thin silicon, which are disposed crosswise, is accommodated inside the support section 11.

Piezoelements 14 are respectively formed at the flexible portions 12 supported at the centers of the four sides of the support section 11 corresponding to the edge portion of the sensor chip 10. A plurality of pads 15 formed of a conductive material such as aluminum (Al) are formed at their corresponding surfaces of the two opposite sides of the support section 11, which are located on the same sides as the surfaces of the flexible portions 12, formed with the piezoelectric elements 14 (all the surfaces of the support section 11 including the two sides formed with the pads 15 are called “pad forming surface 10a of the sensor chip 10”).

The piezoelements 14 formed at the respective flexible portions 12 are respectively internally connected to the predetermined pads 15 formed at the support section 11.

Thus, when the weight section 13 is swung by acceleration applied to the sensor chip 10, changes in the resistance values of the piezoelements 14 due to deformation produced in the respective flexible portions 12 are outputted from the pads 15 as detected signals respectively.

Reference numeral 20 indicates a control chip such as an LSI (Large Scale Integrated circuit). The control chip 20 has one surface formed with a plurality of connecting terminals 21 (refer to FIG. 1) respectively electrically connected to predetermined portions of an unillustrated internal circuit of the control chip 20 (the surface formed with the connecting terminals 21, of the control chip 20 is called “terminal forming surface 20a”) and has the function of converting detected signals outputted from the sensor chip 10 to electric signals or the like and thereby outputting the accelerations of the X-axis, Y-axis and Z-axis.

Reference numeral 23 indicates a fitting concave section, which is a dead-end hole having an opening freely-fit on a rectangular outer surface of the sensor chip 10, said hole being formed in a surface (called “back surface 20b”) of the control chip 20, which is located on the side opposite to the terminal forming surface 20a. The surface (called “back surface 10b of the sensor chip 10”) located on the side opposite to the pad forming surface 10a, of the support section 11 of the sensor chip 10 is mated with its corresponding bottom face 23a by insulative bonding members 24 such as insulation-based die bonding agents.

In FIG. 1, reference numerals 26 indicate wires, each of which is a metal thin line or wire formed of a conductive material such as gold (Au). The wires 26 have the function of electrically connecting between the internal terminals 6 formed at the intermediate stage portion 3 of the case body 2 and the connecting terminals 21 of the control chip 20.

Reference numerals 28 indicate conductive bonding members, each of which is formed of a bonding agent having conductivity, such as a gold bump. The conductive bonding members 28 have the function of electrically connecting the pads 15 formed in the pad forming surface 10a of the sensor chip 10 and the bottom face terminals 5 formed at the bottom face 4a of the storage concave section 4 of the case body 2.

Therefore, the bottom face terminals 5 are respectively disposed at positions corresponding to the pads 15 of the sensor chip 10 at the central part of the bottom face 4a of the storage concave section 4.

The acceleration sensor package 1 having the above configuration is assembled as follows: The pad forming surface 10a of the sensor chip 10 is turned down. The pads 15 formed at the support section 11 are bonded onto their corresponding bottom face terminals 5 formed at the bottom face 4a of the sensor chip 10 by the conductive bonding members 28. The bottom face 23a of the fitting concave section 23 formed at the back surface 20b of the control chip 20 is mated with the back surface 10b of the sensor chip 10 by the insulative bonding members 24. The connecting terminals 21 of the control chip 20 and the internal terminals 6 formed at the intermediate stage portion 3 of the case body 2 are connected by the wires 26 respectively. Thereafter, the cover 7 is adhered onto the upper surface of the side plate of the case body 2 by the adhesive material 8 thereby to seal space of the storage concave section 4 in which the chip laminated body with the sensor chip 10 and the control chip 20 laminated on each other is accommodated.

Thus, the sensor chip 10 of the present embodiment is laminated by directly bonding the pads 15 formed at the pad forming surface 10a thereof onto the bottom face terminals 5 formed at the bottom face 4a of the storage concave section 4 of the case body 2 by the conductive bonding members 28 and directly mating the back surface 20b of the control chip 20 with the back surface 10b of the sensor chip 10 by the insulative bonding members 24. Therefore, a gap or clearance for accommodating or storing the wires 26 for connecting the pads 15 of the sensor chip 10 and the internal terminals 6 or the like becomes unnecessary and the height of the chip laminated body is minimized, thereby making it possible to bring the acceleration sensor package 1 into less thickness.

The bottom face 4a of the storage concave section 4 opposite to the pad forming surface 10a of the sensor chip 10 via space defined using the conductive bonding members 28 can be allowed to function as a stopper for limiting swinging of the weight section 13 of the sensor chip 10. Damage of the flexible portions 12 at the time that an impulsively-generated excessive acceleration has been applied can be prevented.

Further, since the fitting concave section 23 is provided in the back surface 20b of the control chip 20 and the back surface 10b of the sensor chip 10 is mated with the bottom face 23a, the height of the chip laminated body can be further lowered and further thinning of the acceleration sensor package 1 can be achieved.

In the present embodiment as described above, the pads formed at the pad forming surface of the sensor chip are electrically connected to their corresponding bottom face terminals placed at the bottom face of the storage concave section for accommodating the sensor chip and the control chip, which is formed in the case body. Further, the back surface located on the side opposite to the terminal forming surface, of the control chip is mated with the back surface located on the side opposite to the pad forming surface, of the sensor chip, thereby making the wires connected to the pads of the sensor chip unnecessary. Thus, the height of the chip laminated body in which the sensor chip and the control chip are stacked on each other, can be minimized and thinning of the acceleration sensor package can be achieved. Further, the bottom face of the storage concave section can be allowed to function as the stopper for limiting the swinging of the weight section of the sensor chip, and damage of the flexible portions of the sensor chip can be prevented.

The fitting concave section for freely fitting the sensor chip is provided at the back surface of the control chip, and the back surface of the acceleration sensor chip is mated with the bottom face of the fitting concave section, thereby making it possible to further lower the height of the chip laminated body and achieve further thinning of the acceleration sensor package.

Incidentally, although the present embodiment has described that the pads of the sensor chip are provided at the two opposite sides of the support section of the sensor chip, the positions where the pads of the sensor chip are provided are not limited to the above. They may be provided at all sides or three sides of the support section of the sensor chip. In this case, the bottom face terminals are provided at the positions corresponding to the pads.

### Second Preferred Embodiment

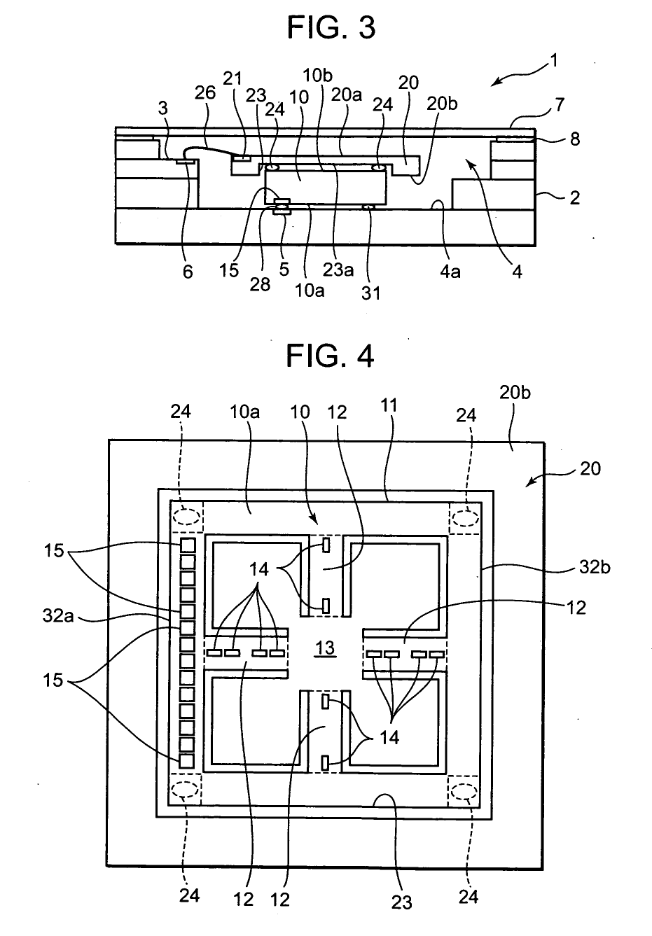

FIG. 3 is an explanatory diagram showing a section of an acceleration sensor package according to a second preferred embodiment, and FIG. 4 is an explanatory diagram of a chip laminated body of the second preferred embodiment as viewed from its pad forming surface side, respectively.

Incidentally, the same reference numerals are respectively attached to components similar to those of the first preferred embodiment, and their description will therefore be omitted.

In FIG. 3, reference numeral 31 indicates an insulation-based adhesive material, which has insulation and is formed by a flexible adhesive that is lower in elastic modulus than each conductive bonding member 28 and abounds relatively in elasticity. The insulation-based adhesive material 31 is of an adhesive composed of silicone rubber, for example.

As shown in FIG. 4, a plurality of pads 15 necessary for a sensor chip 10 of the present embodiment are all formed in one side 32a of a support section 11 corresponding to an edge portion of the sensor chip 10 at a pad forming surface 10a of the sensor chip 10.

Therefore, the pads 15 are not formed in the other side 32b opposite to the one side 32a of the support section 11. Bottom face terminals 5 placed at the central part of a bottom face 4a of a storage concave section 4 of a case body 2 are also formed at the positions corresponding to the pads 15 of the sensor chip 10.

The acceleration sensor package 1 having the above configuration is assembled as follows: The pad forming surface 10a of the sensor chip 10 is turned down. The pads 15 formed at the one side 32a of the support section 11 are bonded onto their corresponding bottom face terminals 5 formed at the bottom face 4a of the storage concave section 4 of the case body 2 by the conductive bonding members 28. The pad forming surface 10a of the other side 32b is mated with the bottom face 4a of the storage concave section 4 by the flexible insulation-based adhesive material 31. A bottom face 23a of a fitting concave section 23 formed at its corresponding back surface 20b of a control chip 20 is mated with its corresponding back surface 10b of the sensor chip 10 by insulative bonding members 24. Connecting terminals 21 of the control chip 20 and internal terminals 6 formed at an intermediate stage portion 3 of the case body 2 are connected by wires 26 respectively. Thereafter, a cover 7 is adhered onto the upper surface of a side plate of the case body 2 by an adhesive material 8 thereby to seal space of the storage concave section 4 in which the chip laminated body is accommodated.

As described above, the sensor chip 10 of the present embodiment is laminated by directly bonding the pads 15 formed at one side 32a of the edge portion of the pad forming surface 10a thereof onto the bottom face terminals 5 formed at the bottom face 4a of the storage concave section 4 of the case body 2 by the conductive bonding members 28, directly mating the other side 32b of the edge portion with the bottom face 4a of the storage concave section 4 by the flexible insulation-based adhesive material 31 and directly mating the back surface 20b of the control chip 20 with the back surface 1Db of the sensor chip 10 by the insulative bonding members 24. Therefore, the height of the chip laminated body is minimized in a manner similar to the first preferred embodiment thereby to make it possible to bring the acceleration sensor package 1 into less thickness. Further, deformation due to thermal expansion of the support section 11 of the sensor chip 10 with a change in temperature within the acceleration sensor package 1 can be prevented using flexibility of the insulation-based adhesive material 31, and a temperature drift caused by the thermal expansion of the support section 11 can be *prevented from occurring.

In the present embodiment as described above, a plurality of pads are formed at one side of an edge portion of a sensor chip and electrically joined to their corresponding bottom face terminals of a storage concave section, and the other side opposite to the one side of the edge portion is mated with its corresponding bottom face of the storage concave section by a flexible insulation-based adhesive material, in addition to effects similar to those of the first preferred embodiments. It is thus possible to prevent deformation due to the thermal expansion of the support section of the sensor chip with a change in temperature within an acceleration sensor package and prevent a temperature drift caused by the thermal expansion of the support section.

While the preferred forms of the present invention have been described, it is to be understood that modifications will be apparent to those skilled in the art without departing from the spirit of the invention. The scope of the invention is to be determined solely by the following claims.

What is claimed is:

1. An acceleration sensor package comprising:
an acceleration sensor chip having a pad forming surface formed with a plurality of pads at at least one edge portion;
a control chip having a terminal forming surface formed with connecting terminals; and
a case body having a storage concave section for accommodating the acceleration sensor chip and the control chip therein and bottom face terminals respectively disposed at positions corresponding to the pads at a bottom face of the storage concave section,
wherein the pads of the acceleration sensor chip are respectively electrically connected to the bottom face terminals of the case body, and
wherein a back surface located on the side opposite to the terminal forming surface, of the control chip is mated with a back surface located on the side opposite to the pad forming surface, of the acceleration sensor chip.

2. The acceleration sensor package according to claim 1, wherein a fitting concave section for freely fitting the acceleration sensor chip is provided at the back surface of the control chip, and
wherein the back surface of the acceleration sensor chip is mated with a bottom face of the fitting concave section.

3. The acceleration sensor package according to claim 1, wherein the pads are formed at one side of the edge portion of the acceleration sensor chip, and
wherein the pads are respectively electrically joined to the bottom face terminals by conductive bonding members, and the other side opposite to the one side of the edge portion is mated with the bottom face of the storage concave section by an insulation-based adhesive material lower in elastic modulus than the conductive bonding members.

4. The acceleration sensor package according to claim 2, wherein the pads are formed at one side of the edge portion of the acceleration sensor chip, and
wherein the pads are respectively electrically joined to the bottom face terminals by conductive bonding members, and the other side opposite to the one side of the edge portion is mated with the bottom face of the storage concave section by an insulation-based adhesive material lower in elastic modulus than the conductive bonding members.
